(19) United States
(12) Patent Application Publication
(10) Pub. No.: US 2017/0081190 A1
(43) Pub. Date: Mar. 23, 2017

(54) Novel Series of Carbon Allotropes: Novamene

(71) Applicants: Larry Burchfield, Richland, WA (US); Mohamed Al Fahim, Abu Dhabi (AE)

(72) Inventor: Larry Burchfield, Richland, WA (US)

(21) Appl. No.: 15/153,752

(22) Filed: May 13, 2016

Related U.S. Application Data
(60) Provisional application No. 62/221,274, filed on Sep. 21, 2015.

(51) Int. Cl. C01B 31/02; H01L 29/16; H01L 51/00; H01B 1/04

(52) U.S. Cl. CPC C01B 31/02; H01B 1/04; H01L 29/1602; H01L 29/1606; H01L 51/0047; H01L 51/0048; H01L 51/0558

(57) ABSTRACT

The present invention provides a series of new and useful synthetic carbon allotropes. The carbon allotropes contain at least two inner hexagonal rings of 6 carbon atoms, which are characterized by hybridized sp² bonds, as commonly found in graphene structure. The inner hexagonal rings are located in a central position within the carbon allotropes and bonded to each other in various configurations. Surrounding the hexagonal rings are additional carbon atoms, characterized by sp³ hybridized bonding, found in diamond, and more specifically in hexagonal diamond, also known as Lonsdaleite. These surrounding Lonsdaleite structures are bonded to and surround the inner hexagonal rings and support them in a central position within the carbon allotropes.

### CROSS-REFERENCE TO RELATED APPLICATIONS

This patent application claims the benefit of U.S. Provisional Application Ser. No. 62/221274, filed on 21 Sep. 2015, and titled “A Novel Carbon Allotrope Novamene”.

### BACKGROUND OF THE INVENTION

Field of Invention

The invention relates to novel carbon allotropes and compositions and uses thereof.

Description of Related Art

Elemental carbon occurs throughout nature in a wide variety of allotropic forms. This wide variety of allotropic forms is attributed to carbon being the only element in the periodic table known to have isomers with 0, 1, 2, or 3 dimensions. The carbon atom can hybridize electronic states in several different valence bonds which allows for a variety of different atomic bonding configurations. The isomers can have sp, sp² or sp³ hybridization in the valence electron orbitals.

As can be seen in FIG. 1a through 1h there are eight known allotropes of carbon: a) diamond, b) graphite, c) Lonsdaleite, d) C60 (Buckminsterfullerene or buckyball), e) C540, f) C70, g) amorphous carbon, and h) single-walled carbon nanotube, or buckytube.

Diamond is one of the most well-known carbon allotrope. The carbon atoms are arranged in a lattice, which is a variation of the face-centered cubic crystal structure. Each carbon atom in a diamond is covalently bonded to four other carbons in a tetrahedron, as seen in FIG. 1a. These tetrahedrons together form a three-dimensional network of six-membered carbon rings in the chair conformation, allowing for zero bond-angle strain. This stable network of covalent bonds and hexagonal rings is the reason that diamond is so incredibly strong as a substance.

As a result, diamond exhibits the highest hardness and thermal conductivity of any bulk material. In addition, its rigid lattice prevents contamination by many elements. The surface of diamond is lipophillic and hydrophobic, which means it cannot get wet by water but can be in oil. Diamonds do not generally react with any chemical reagents, including strong acids and bases.

Graphite is another allotrope of carbon and unlike diamond, it is an electrical conductor and a semi-metal. Graphite is the most stable form of carbon under standard conditions and is used in thermochemistry as the standard state for defining the heat of formation of carbon compounds. As seen in FIG. 1b, graphite has a layered, planar structure. In each layer, the carbon atoms are arranged in a hexagonal lattice with separation of 0.142 nm, and the distance between planes (layers) is 0.335 nm. The two known forms of graphite, alpha (hexagonal) and beta (rhombohedral), have very similar physical properties (except that the layers stack slightly differently). The hexagonal graphite may be either flat or buckled. The alpha form can be converted to the beta form through mechanical treatment, and the beta form reverts to the alpha form when it is heated above 1300° C. Graphite can conduct electricity due to the vast electron delocalization within the carbon layers; as the electrons are free to move, electricity moves through the plane of the layers.

A single layer of graphite is called graphene. This material displays extraordinary electrical, thermal, and physical properties. It is an allotrope of carbon whose structure is a single planar sheet of sp² bonded carbon atoms that are densely packed in a honeycomb crystal lattice. The carbon-carbon bond length in graphene is ˜0.142 nm, and these sheets stack to form graphite with an interplanar spacing of 0.335 nm. Graphene is the basic structural element of carbon allotropes such as graphite, charcoal, carbon nanotubes, and fullerenes. Graphene is a semi-metal or zero-gap semiconductor, allowing it to display high electron mobility at room temperature.

Another known allotrope of carbon, Lonsdaleite, is also known as “hexagonal diamond”, due to its crystal structure which has a hexagonal lattice, which is depicted in FIG. 1c. The diamond structure is typically made up of interlocking six carbon atoms, which exist in the chair conformation. However, in Lonsdaleite, some rings are in the boat conformation instead. In diamond, all the carbon-to-carbon bonds, both within a layer of rings and between the layer of rings are in the staggered conformation, which causes all four cubic-diagonal directions to be equivalent. Whereas in Lonsdaleite, the bonds between the layers are in the eclipsed conformation, which defines the axis of hexagonal symmetry.

Amorphous carbon refers to carbon that does not have a crystalline structure, as is evident by the structure depicted in FIG. 1g. Even though amorphous carbon can be manufactured, there still exist some microscopic crystals of graphite-like or diamond-like carbon. The properties of amorphous carbon depend on the ratio of sp² to sp³ hybridized bonds present in the material. Graphite consists purely of sp² hybridized bonds, whereas diamond consists purely of sp³ hybridized bonds. Materials that are high in sp³ hybridized bonds are referred to as tetrahedral amorphous carbon (owing to the tetrahedral shape formed by sp³ hybridized bonds), or diamond-like carbon (owing to the similarity of many of its physical properties to those of diamond).

Carbon nanomaterials make up another class of carbon allotropes. Fullerenes (also called buckyballs) are molecules of varying sizes composed entirely of carbon that take on the form of hollow spheres, ellipsoids, or tubes. Buckyballs and buckytubes have been the subject of intense research, both because of their unique chemistry and for their technological applications, especially in materials science, electronics, and nanotechnology. Carbon nanotubes are cylindrical carbon molecules that exhibit extraordinary strength and unique electrical properties and are efficient conductors of heat. Carbon nanobuds are newly discovered allotropes in which fullerene-like “buds” are covalently attached to the outer side walls of a carbon nanotube. Nanobuds therefore exhibit properties of both nanotubes and fullerenes.

Pure carbon and its various known allotropic forms described above provide many currently useful commercial and research applications. For example, the high thermal conductivity of diamond along with its electrically insulative properties allows for its widespread use as a heat sink material for certain solid state devices in the microelectronics industry. Graphite has been used successfully as a lubricant and a catalyst support material.

### SUMMARY

The present invention provides a series of new and useful synthetic carbon allotropes, which for purposes of the present disclosure will be termed “Novamene” allotropes. Due to the unique chemical structure of the presently disclosed carbon allotropes, compositions comprising the allotropes can be useful for incorporation for a variety of materials, including, but not limited to those utilized for Hall effect sensors, transistors, transparent conducting electrodes and piezoelectric materials.

The carbon allotropes contain at least two inner hexagonal rings of 6 carbon atoms, which are characterized by hybridized sp² bonds, as commonly found in graphene structure. The inner hexagonal rings are located in a central position within the carbon allotropes and bonded to each other in various configurations. Surrounding the hexagonal rings are additional carbon atoms, characterized by sp³ hybridized bonding, found in diamond, and more specifically in hexagonal diamond, also known as Lonsdaleite. These surrounding Lonsdaleite structures are bonded to and surround the inner hexagonal rings and support them in a central position within the carbon allotropes.

In one embodiment, a carbon allotrope contains two centrally located inner hexagonal rings supported by surrounding carbons in a Lonsdaleite structure. In further embodiments the carbon allotrope contains three centrally located inner graphene rings, and even further embodiments, the allotrope contains four centrally located inner graphene rings.

The unique combination of the two different carbon structures within the carbon allotropes, the inner hexagonal rings which form graphene crystals and the surrounding carbons in a Lonsdaleite configuration, the present carbon allotropes exhibit diverse chemical, physical and mechanical properties. The inner hexagonal rings are characterized as having high carrier mobility, which results in the central portion of the allotrope being capable of electron conductivity, whereas the surrounding carbon atoms, formed in the Lonsdaleite configuration has very low carrier mobility and results in a surrounding structure which is insulative. The conductive portion of the molecule is thereby centralized and isolated within the molecule by the insulative Lonsdaleite outer structure of the allotrope.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

In the drawings:

FIG. 1a-h illustrates the structures of various known carbon allotropes.

FIG. 2 illustrates structures of known carbon allotropes.

FIG. 3 illustrates a front view of one embodiment of the carbon allotropes of the present invention.

FIG. 4 illustrates a front view of one embodiment of the carbon allotropes of the present invention.

FIG. 5 illustrates a front view of one embodiment of the carbon allotropes of the present invention.

FIG. 6 illustrates a front view of one embodiment of the carbon allotropes of the present invention.

FIGS. 7 and 8 illustrate a front view of one embodiment of the carbon allotropes of the present invention.

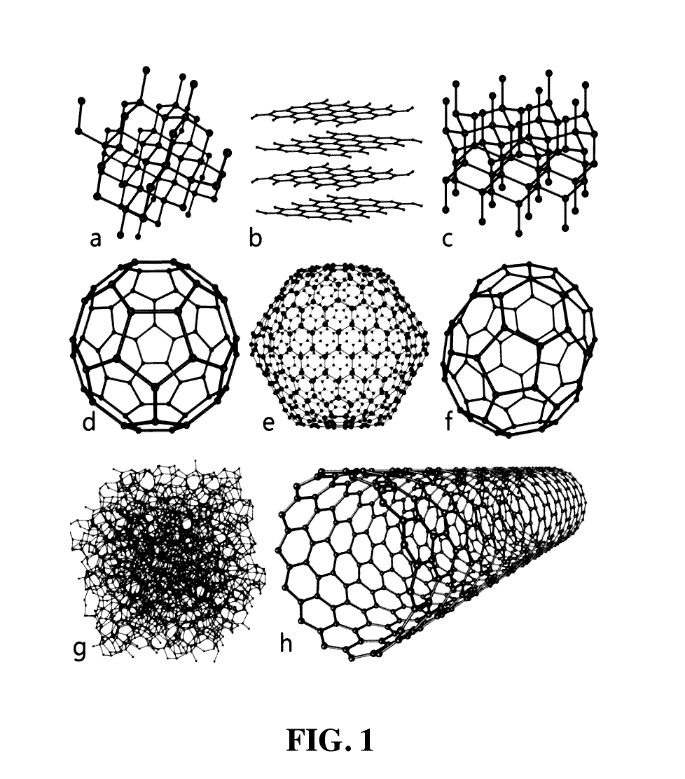

### DETAILED DESCRIPTION OF THE INVENTION

In the following Detailed Description, reference is made to the accompanying drawings, which form a part hereof, and in which is shown by way of illustration specific embodiments in which the invention may be practiced. Wherever possible, the same reference numbers are used in the drawings and the description to refer to the same or like parts. Directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

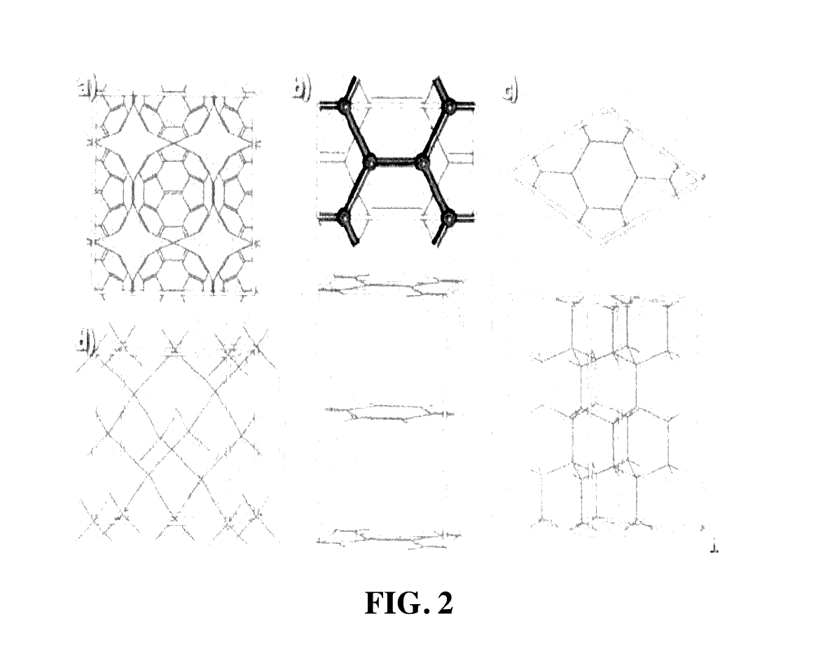

The present invention pertains to synthetic new carbon allotropes, which contain at least two inner hexagonal rings 10 of six carbon atoms centrally located within the carbon allotrope. The carbon atoms of the inner hexagonal rings are bonded together by hybridized sp² bonds 20, as commonly found in a graphene structure. FIGS. 2 through 6 illustrate various views of the structure of the presently disclosed carbon allotropes.

The inner hexagonal rings 10 are located in a central position within the carbon allotrope and bonded to each other in various configurations, as shown in FIGS. 2 through 6. Surrounding the hexagonal rings 10 are additional carbon atoms 30, characterized by sp³ hybridized bonds 40, found in diamond, and more specifically in hexagonal diamond, also known as Lonsdaleite. This surrounding Lonsdaleite structures 50 are bonded to and surround the inner hexagonal rings 10 and support them in a central position within the carbon allotrope.

Structure of Novamene and Comparison with Known Carbon Allotropes

For purposes of comparison with existing carbon allotropes and for a better understanding of the structure of these novel carbon allotropes, the following is a discussion of known carbon allotropes, including diamond, graphite (where graphene is a single layer of graphite), Lonsdaleite and buckminsterfullerenes (C60).

For example, the motif of the single hexagonal rings of carbon surrounded by three carbon pentagons is similar to the fundamental repeating pattern in buckiminsterfullerenes, also known as “buckyballs”, as depicted in FIG. 2a. Buckyballs, are spherical fullerene molecules with the formula C60. They have a cage-like fused-ring structure which resembles a soccer ball, made of twenty hexagons and twelve pentagons, with a carbon atom at each vertex of each polygon and a bond along each polygon edge.

In the buckyball structure, the carbon to carbon distances in the hexagonal rings surrounded by a total of six alternating pentagons and hexagons are on the order of 1.45-1.49 Angstroms. It is the folding up of these alternating hexagons and pentagons surrounding the central hexagonal carbon ring that leads to the classic ball shape of fullerenes In contrast, the grouping of three pentagons surrounding a central hexagonal ring remains “in plane” in the present carbon allotrope structure, however, members of the six and seven atom carbon rings “pop up” to the next plane.

With respect to the vertical spacing of the 6 carbon inner hexagonal rings in the presently disclosed Novamene structure, which are not bonded together, graphite shown in FIG. 2b and Lonsdaleite, shown in FIG. 2c lend a useful comparison.

In graphite, infinite sheets of hexagonal carbon rings make up the layered characteristic of this structure. The hexagonal layers in graphite are offset by half a unit cell between the layers, that is, a carbon ring in one layer does not sit exactly above a carbon ring in the next layer, as can be seen in FIG. 2b. Carbon-to-carbon distances in the rings of graphite are approximately 1.418 Angstroms and each layer is separated by 3.348 Angstroms perpendicular to the carbon sheets.

Another known allotrope of carbon, Lonsdaleite, is also known as “hexagonal diamond”, due to its crystal structure which has a hexagonal lattice. The diamond structure of typically made up of interlocking six carbon atoms, which exist in the chair conformation. However, in Lonsdaleite, some rings are in the boat conformation instead. In diamond, all the carbon-to-carbon bonds, both within a layer of rings and between the layer of rings are in the staggered conformation, which causes all four cubic-diagonal directions to be equivalent. Whereas in Lonsdaleite, the bonds between the layers are in the eclipsed conformation, which defines the axis of hexagonal symmetry.

In Lonsdaleite, the hexagonal carbon rings are situated directly on top of one another between layers, as is shown in FIG. 2c. The rings however are kinked rather than planar, such that the shorter carbon-to-carbon distances, about 1.545 Angstroms, are bonded between planes, while longer carbon-to-carbon distances of 2.575 Angstroms remain unbonded. Additional bonding constraints are the carbon-to-carbon distances in the hexagonal rings, of 1.543-1.545 Angstroms, and these rings are connected both in-plane and perpendicular to the plane.

Lastly, in the present carbon allotropes (Novamene), it can be said that a diamond-like, Lonsdaleite structures 50 aid in connecting the repeating units to one another. In diamond, every carbon is bonded to four other carbon atoms in a tetrahedral conformation, as depicted in FIG. 2d. The carbon atoms are arranged in a variation of the face-centered cubic crystal structure called a diamond lattice. The diamond allotrope has bond lengths of 1.544 Angstroms in all directions.

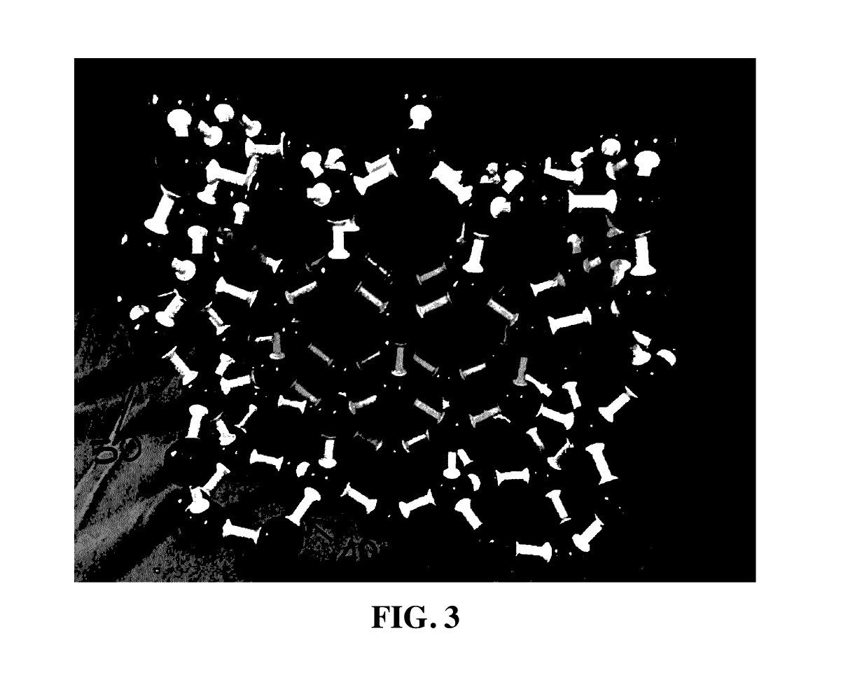

Referring now to FIG. 3, one embodiment of the carbon allotrope of the present invention is shown, using a three dimensional ball-and-stick model. The centrally located inner hexagonal rings 10 of the carbon allotrope, consist of six bonded carbons, which are connected by sp2 hybridized bonds 20 (depicted in grey color). The inner hexagonal rings 10 form graphene crystals centralized within the carbon allotrope. As can be seen in FIG. 3, in this embodiment, the carbon allotrope contains two inner hexagonal rings 10 bonded to each other in a single layer of the allotrope. A repeating layer of the allotrope is also depicted below or above (depending on the frame of reference) the top or bottom layer containing the two inner hexagonal rings 10. In each layer the inner hexagonal rings 10 reside directly above or below each other, however there are no interplanar bonds between the inner hexagonal rings 10 between the layers, which are repeating units of the carbon allotrope. That is to say the inner hexagonal rings 10 are only bonded to an additional ring in a single plane only and there is no bond interaction with the inner hexagonal rings 10 in the planes above or below.

As can be further seen in FIG. 3, surrounding the hexagonal rings 10 are additional carbon atoms 30, connected to each other by sp³ hybridized bonds 40, as found Lonsdaleite configurations. These surrounding Lonsdaleite structures 50 are bonded to and surround the inner hexagonal rings 10 and support them in a central position within the carbon allotrope. All atoms are bonded to four other atoms in the present carbon allotrope, except for those in the hexagonal inner rings 10, which are only bonded to three other carbon atoms.

The carbons of hexagonal inner ring 10 shown in FIG. 3 are characterized by sp² hybridization. Each carbon atom in the hexagonal inner rings 10 undergoes sp² hybridization and the unhybridized p-orbitals on each carbon atoms overlap sideways to produce a pi system above and below the plane of the hexagonal inner rings. Whereas, the other carbon atoms 30, as previously discussed, are bonded by bonds 40 in FIG. 3 and are characterized by sp³ hybridization, to form Lonsdaleite structures 50.

Therefore, it can be said that the presently disclosed carbon allotrope consist of a centralized graphite core backbone, which is held together by surrounding Lonsdaleite structures 50. The Lonsdaleite structures 50 include interlocking 6 carbon rings in chair or boat conformations. The bonds between the layers are in eclipsed conformation, which defines the axis of the hexagonal symmetry.

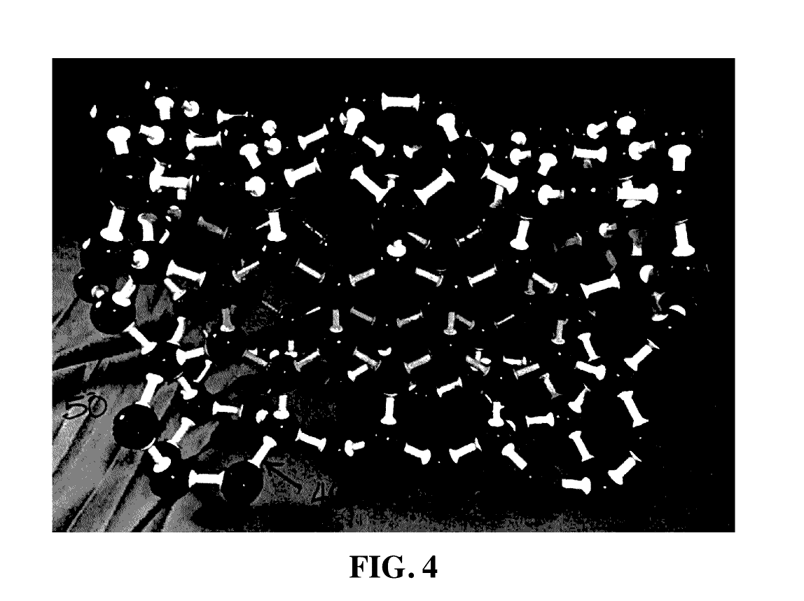

The present carbon allotrope can further contain more than two centrally located inner hexagonal rings 10, including two and three inner hexagonal rings 10, as shown by the embodiments depicted in FIGS. 4-8.

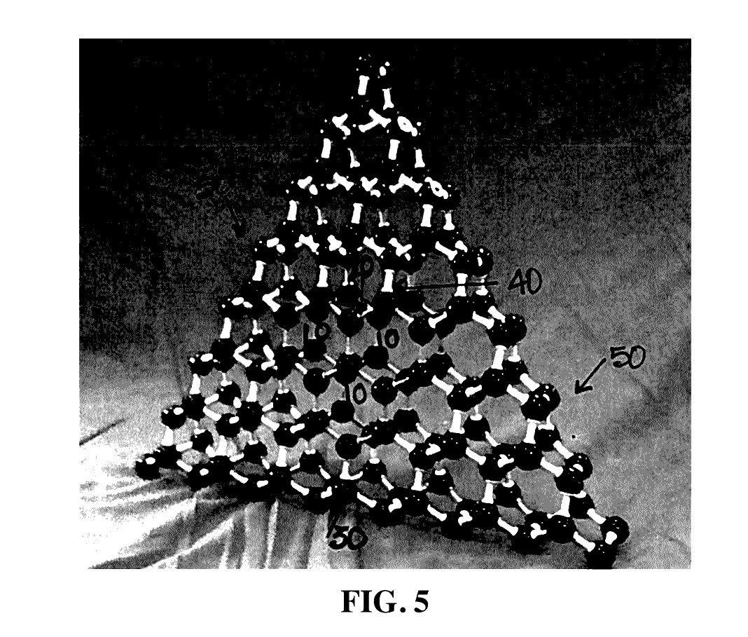

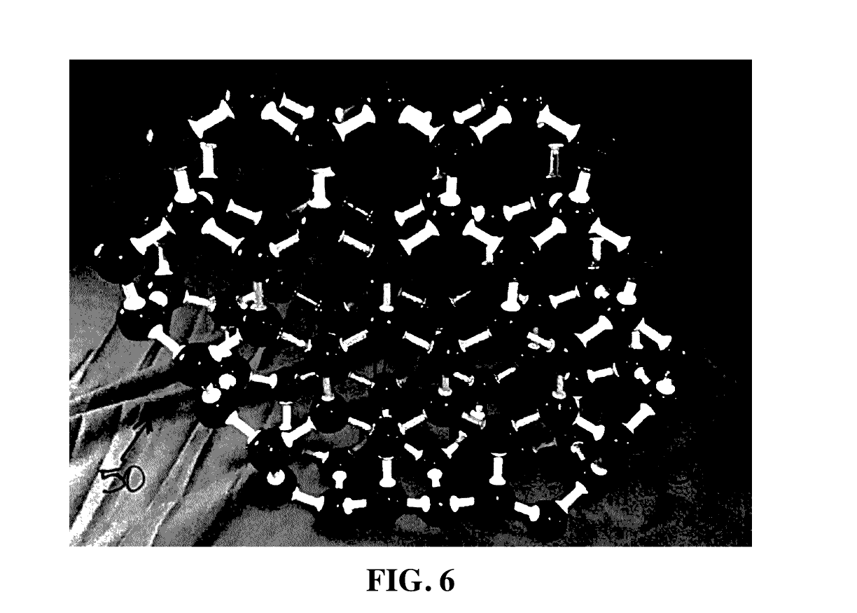

In FIGS. 4, 5 and 6, further embodiments of the present carbon allotrope are shown, which contain three centrally located inner hexagonal rings 10. FIG. 4 shows the carbon allotrope having three inner hexagonal rings 10, in a single line adjacent to each other, bonded by sp2 hybridized bonds 20. Similarly to earlier described embodiments, the inner hexagonal rings 10 in this embodiment are supported in a central position by bonding to other carbon atoms 30, which are bonded to each other by sp3 hybridized bonds 40, to form Lonsdaleite structures 50 around and supporting the three inner hexagonal rings 10. Therefore, it can be said these embodiments, three graphene crystals are supported and isolated in a central location within the carbon allotrope, by the surrounding Lonsdaleite structures. In FIGS. 5 and 6, a further embodiments containing three inner hexagonal rings 10 are shown.

In FIG. 5, the inner hexagonal rings 10 are formed centrally within the carbon allotrope in a triangular geometry, so that the supporting Lonsdaleite structures 50 also result in a molecule of triangular configuration. As with the previous embodiments, two layers or repeating units of the carbon allotrope are shown in FIG. 5, wherein an additional layer of inner hexagonal rings 10 resides in a plane directly above or below the top or bottom inner hexagonal rings (depending on the frame of reference). There is no interplanar bonding between the inner hexagonal rings 10 of residing in each plane shown in FIG. 5. Instead, the inner hexagonal rings 10 are held in the central position and residing above or below each other through bonding with the other carbons 30, which form the supporting Lonsdaleite structures 50. FIG. 6 also depicts a further embodiment having three inner hexagonal rings 10 in a central position within the carbon allotrope, whereas now the inner hexagonal rings 10 are located in a different configuration, as compared to the configurations shown in FIGS. 4 and 5. Similarly to the embodiments of FIGS. 4 and 5, a second layer or repeating unit is shown in FIG. 6, where an additional layer of inner hexagonal rings 10 is shown above or below in a different plane. Again here, no interplanar bonding exists between these inner hexagonal rings 10 in the planes above or below, and the inner hexagonal rings 10 are only bonded to the other carbons 30 which form the Lonsdaleite structures 50 surrounding the central graphene crystals.

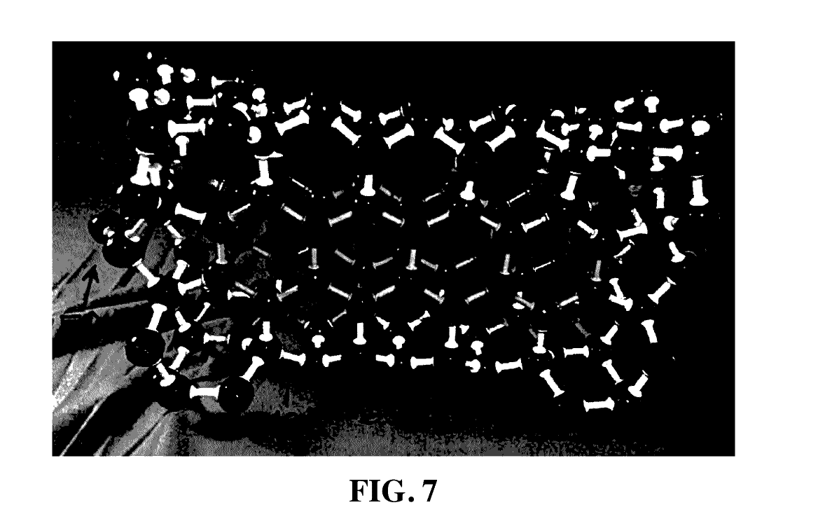

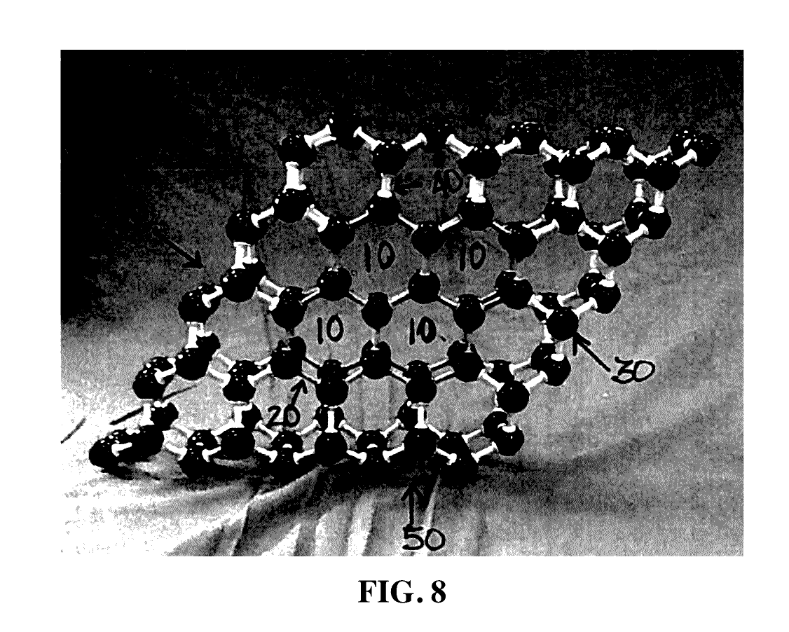

Moving now to FIGS. 7 and 8, a further embodiment of the present invention is shown, wherein the carbon allotrope contains four centrally located inner hexagonal rings 10. The embodiment shown in FIG. 7 shows four inner hexagonal rings 10, aligned in a single direction. Whereas the embodiment shown in FIG. 8, contains four inner hexagonal rings 10, bonded to each other with two of the rings stacked on top and two rings below in a single plane, as viewed from a front side perspective of the allotrope. A second layer or repeating unit of the centrally located inner hexagonal rings 10 is shown in another plane behind the first plane. The Lonsdaleite structures 50 surrounding the hexagonal inner rings 10 in this embodiment give the carbon allotrope a rhomboidal shape, as can be seen in FIG. 8.

As has been shown by the varying embodiments and depictures in FIGS. 3 through 8, multiple configurations of the carbon allotrope are possible, all within the confines of having centrally located inner hexagonal graphene rings 10, containing six carbon atoms that are bonded by sp2 hybridized bonds, surrounded by other carbon atoms bonded by sp3 hybridization, which create Lonsdaleite structures around the centrally located graphene inner rings 10. Depending on the number of inner hexagonal graphene rings 10 present in the carbon allotrope, the total number of carbons in the allotrope that are sp2 and sp3 hybridized will vary, as illustrated in the following Table 1 and as evident by FIGS. 3 through 8.

TABLE 1

| | | No. of sp2 | No. of sp3 | No. of sp3 | |
|---|---|---|---|---|---|
| | | carbon atoms | carbon atoms | carbon atoms | Total |
| No. of | | bound in | bound in plane | bound in plane | number of |
| hexagonal | No. of possible | hexagonal | of hexagonal | between | carbon |
| rings | allotropes | rings | rings | hexagonal rings | atoms |
| 1 | 1 | 6 | 12 | 12 | 30 |
| 2 | 1 | 10 | 16 | 16 | 42 |
| 3 | 3 | 14 | 20 | 20 | 54 |
| 4 | 7 | 18 | 24 | 24 | 66 |

The number of possible carbon allotropes also changes depending on the number of inner hexagonal rings 10 present within the allotrope. As can be seen in the second column in the Table 1 above, if one inner hexagonal ring is present, this results in one configuration of the carbon allotrope. An embodiment of this carbon allotrope is subject of another patent application, filed earlier this year. If two inner hexagonal rings 10 are present, then one carbon allotrope is possible, as shown in the embodiment of FIG. 3, as previously described above. As can be seen in Table 1, if three inner hexagonal rings 10 are present, then three different carbon allotropes are possible, as depicted in FIGS. 4-6. Similarly, with four inner hexagonal rings 10 present, there are seven different carbon allotrope configurations possible, and two such embodiments the allotropes having four inner hexagonal rings 10 are is shown in FIGS. 7 and 8, and previously described above. As can be seen by the foregoing, various embodiments of allotropes are possible, depending on the number of inner hexagonal rings 10 present. Further to the above listed embodiments in Table 1, additional allotropes are possible, with 5, 6, 7, 8 and so on inner hexagonal rings 10. Therefore, the available number of carbon allotropes possible, is not limited to those disclosed in this application, as the depictions and descriptions incorporated herein are merely exemplary and not intended to limit the scope of the invention.

Properties and Utilization of the Carbon Allotrope

Graphene is known to behave as a zero-gap semiconductor, allowing it to display high electron mobility at room temperature. It can function as either a n-type or p-type semiconductor, which makes it a far more versatile component than regular silicon based semiconductors. Graphene also exhibits a pronounced response to perpendicular external electric files, which aid in its potential utilization as a field-effect transistor (FET). Additionally, graphene's high electrical conductivity and high optical transparency make it a suitable candidate for utilization in transparent conducting electrodes, which are required for such applications as touchscreens, liquid crystal displays, organic photovoltaic cells and organic light emitting diodes.

In particular, graphene's mechanical strength and flexibility are highly advantageous when compared to prior metallic or metal oxide based films used in many of the above applications, which are known to be brittle and thereby undesirable for various applications, especially those which require a mechanically stable but flexible component.

Due to its various unique chemical and physical properties graphene has been shown to be successfully utilized in various applications and components, including, but not limited to, integrated circuits, optoelectronics, Hall effect sensors, quantum dots, optical absorption/modulation, infrared light detection, photovoltaic cells, conductive electrodes, fuel cells, supercapacitors, molecular absorption sensors and piezoelectric devices.

Due to the unique structure of the presently disclosed carbon allotrope, which includes an electron conducting graphene based central portion surrounded by an insulating outer Lonsdaleite structure, various of the above mentioned applications and devices can advantageously incorporate compositions of the carbon allotrope. For example, for the production of integrated circuits, the incorporation of the presently disclosed carbon allotrope would provide high carrier mobility due to the central graphene core, while resulting in low noise due to the insulating properties of the outer Lonsdaleite structures.

Doping and Synthesis Methods of the Carbon Allotrope

For further enhancement of conducting capabilities the carbon allotrope is capable of being doped with a metal element, including but not limited to gold or silver.

Further doping with heteroatoms such as boron, nitrogen, sulfur, phosphor and silicon is also envisioned. The purpose of heteroatomic doping is aimed at altering some of the important properties of the graphene portion of the allotrope, including electrical (electron density and semiconducting character), mechanical (improvement of Young's modulus), and chemical (change of reactivity, creation of catalytically active centers). There are three basic ways that nitrogen can be incorporated into the graphene structure of the carbon allotrope. (1) Substitution, where N is coordinated to three C atoms in sp² like fashion, which induces sharp localized states above the Fermi level associated with the injection of additional electrons into the structure. (2) Pyridine-like substitution, where N is arranged around a vacancy, since the valency of the nitrogen can be satisfied by two sp² bonds, a delocalised p-orbital, and a lone pair in the remaining sp2 orbital, pointing at the vacancy. (3) Chemical adsorption of N2 molecules. Nitrogen contains one electron more than carbon; therefore, substitutional doping of nitrogen within graphene will n-dope the structure, enhancing the number of electronic states at the Fermi level depending on the location and concentration of dopant.

The presently disclosed carbon allotropes can be synthesized through various techniques presently known and existing in the art. These include but are not limited to chemical vapor deposition (CVD), plasma enhanced chemical vapor deposition (PECVD), filament assisted chemical vapor deposition, arc discharge or laser ablation methods and molecular printing. The CVD method is commonly known in the art, and utilizes a carbon containing source, usually in gaseous form, which is decomposed at elevated temperatures and passes over a transition metal catalyst (typically Fe, Co, Ag or Ni). CVD is known to produce a high yield of carbon allotropes, although more accurate structures are generally capable of production through arc deposition or laser ablation methods.

While selected embodiments have been selected to be illustrated of the present invention, and specific examples have been described herein, it will be obvious to those skilled in the art that various changes and modifications may be aimed to cover in the appended claims. It will, therefore, be understood by those skilled in the art that the particular embodiments of the invention presented here are by way of illustration only, and are not meant to be in any way restrictive; therefore, numerous changes and modifications may be made, and the full use of equivalents resorted to, without departing from the spirit or scope of the invention as outlined in the appended claims.

1. A composition of matter comprising a carbon allotrope, said carbon allotrope having at least two inner hexagonal rings located within a single plane, having six carbon atoms bonded together by sp2 hybridized bonds, wherein said at least two inner hexagonal rings are centrally located within the carbon allotrope, and wherein said at least two inner hexagonal rings are bonded to and supported in said central location through bonding with additional carbon atoms by sp3 hybridized bonds.

2. A composition of matter as in claim 1, wherein said at least two inner hexagonal rings of the carbon allotrope are graphene crystals.

3. A composition of matter as in claim 1, wherein said additional carbon atoms bonded by sp3 hybridized bonds form Lonsdaleite structures supporting said at least two inner hexagonal rings.

4. A composition of matter as in claim 1, wherein said carbon allotrope comprises at least three inner hexagonal rings, centrally located within said carbon allotrope.

5. A composition of matter as in claim 1, wherein said carbon allotrope comprises at least four inner hexagonal rings, centrally located within said carbon allotrope.

6. A composition of matter as in claim 1, wherein said carbon allotrope further comprises a repeating layer containing at least two additional inner hexagonal rings, disposed directly above or below said at least two inner hexagonal rings.

7. A composition of matter as in claim 6, wherein said at least two additional inner hexagonal rings and said two inner hexagonal rings do not contain any interplanar bonding to each other.

8. A composition of matter according to claim 1, wherein the carbon allotrope is doped with a metallic element, selected from a group consisting of silver and gold.

9. A composition of matter according to claim 1, wherein the carbon allotrope is doped with a heteroatom, selected from a group consisting of boron, nitrogen, sulfur, phosphor and silicon.

10. A composition of matter according to claim 1, wherein the carbon allotrope is doped with an n-type or p-type material for the formation of a transistor.

11. A composition of matter according to claim 1, wherein the carbon allotrope in said composition is incorporated in devices or applications selected from a group consisting of integrated circuits, optoelectronic devices, semiconductor devices, Hall effect sensors, quantum dots, optical absorption/modulation device, infrared light detection devices, photovoltaic cells, conductive electrodes, fuel cells, supercapacitors, molecular absorption sensors and piezoelectric devices.
